(19) United States
(12) Patent Application Publication
(10) Pub. No.: US 2025/0089366 A1
(43) Pub. Date: Mar. 13, 2025

(54) DISPLAY PANEL AND ELECTRONIC DEVICE

(71) Applicant: WUHAN CHINA STAR OPTOELECTRONICS TECHNOLOGY CO., LTD., Wuhan, Hubei (CN)

(72) Inventors: Yue LI, Wuhan, Hubei (CN); Bo LIU, Wuhan, Hubei (CN); Qiang GONG, Wuhan, Hubei (CN)

(73) Assignee: WUHAN CHINA STAR OPTOELECTRONICS TECHNOLOGY CO., LTD., Wuhan, Hubei (CN)

(21) Appl. No.: 18/558,177

(22) PCT Filed: Jun. 29, 2023
(86) PCT No.: PCT/CN2023/103882

§ 371 Date: Oct. 30, 2023

(30) Foreign Application Priority Data
Sep. 21, 2022 (CN) 202211152835.X

(51) Int. Cl. H01L 27/12

(52) U.S. Cl. CPC H10D 86/60; H10D 86/443

(57) ABSTRACT

A display panel and an electronic device are provided. In the display panel, first line groups and second line groups are arranged in different layers. In the first line groups, there is a voltage difference between every adjacent pair of gate lines. In the second line groups, there is also a voltage difference between every adjacent pair of gate lines. When a short circuit occurs between adjacent gate lines in the same layer, there is a noticeable change in the voltage on the gate lines, which can be detected through a cell test, effectively reducing the chances of missed detections.

### FIELD OF DISCLOSURE

The present application relates to a field of display technology, and in particular, to a display panel and an electronic device.

### DESCRIPTION OF RELATED ART

In the manufacturing process of display panels, in order to detect defective products in a timely manner, a cell test is performed on the display panels. Typically, a detection circuit capable of identifying faults such as signal line short-circuits is designed on an array substrate. For example, a gate detection circuit is used to detect gate scan lines. To improve detection efficiency, two types of detection signals are often employed. Additionally, in order to reduce borders of the display panel, metal lines used to transmit these two types of detection signals are arranged in two separate metal layers, with each metal layer carrying one type of detection signal. However, when a short-circuit occurs between adjacent metal lines in the same metal layer, since it is a short-circuit between identical signals, it cannot be detected as a defect through the cell test. This can lead to missed detections.

### SUMMARY OF INVENTION

This application provides a display panel and an electronic device to alleviate the technical issue of missed detections in the existing display panel during the cell test.

In order to solve the above technical issues, the present application provides a solution as follows.

The present application provides a display panel, including a display area and a first non-display area located on one side of the display area, the display panel further including:
a substrate;
a plurality of gate scan lines disposed on the substrate and located in the display area, wherein each of the gate scan lines extends along a first direction, and the gate scan lines are arranged at intervals along a second direction;
a plurality of first line groups disposed on the substrate and located in the first non-display area, wherein each of the first line groups includes at least two gate lines extending along the first direction, each of the gate lines is electrically connected to a corresponding one of the gate scan lines, and every two adjacent gate lines exhibit a voltage difference; and
a plurality of second line groups disposed on the substrate and located in the first non-display area, wherein each of the second line groups includes at least two gate lines extending along the first direction, each of the gate lines is electrically connected to a corresponding one of the gate scan lines, and every two adjacent gate lines exhibit a voltage difference;
wherein the first line groups and the second line groups are located in different layers, and an orthographic projection of the gate lines in the second line groups projected on the substrate is alternately arranged with an orthographic projection of the gate lines in the first line groups projected on the substrate.

In the display panel according to one embodiment of the present application, each of the first line groups further includes a plurality of connecting lines, and in the same first line group, each of the connecting lines is electrically connected to a corresponding one of the gate lines, and every two adjacent connecting lines exhibit a voltage difference;
each of the second line groups further includes a plurality of connecting lines, and in the same second line group, each of the connecting lines is electrically connected to a corresponding one of the gate lines, and every two adjacent connecting lines exhibit a voltage difference; and
an orthographic projection of the connecting lines in the first line groups projected on the substrate at least partially overlaps with an orthographic projection of the connecting lines in the second line groups projected on the substrate.

In the display panel according to one embodiment of the present application, a number of the gate lines in the first line group is equal to a number of the gate lines in the second line group, and a voltage on each gate line in the first line group is equal to a voltage on the corresponding gate line in the second line group.

In the display panel according to one embodiment of the present application, each of the first line groups includes a first gate line and a second gate line arranged adjacent to each other, and each of the second line groups includes a third gate line and a fourth gate line arranged adjacent to each other, wherein a voltage on the first gate line is equal to a voltage on the third gate line, and a voltage on the second gate line is equal to a voltage on the fourth gate line.

In the display panel according to one embodiment of the present application, the display panel further includes a plurality of third line groups and a plurality of fourth line groups arranged in a same layer as the first line groups, wherein one of the third line groups and one of the fourth line groups are disposed between every two adjacent ones of the first line groups, each of the third line groups and the fourth line groups comprises at least two gate lines, every adjacent pair of the gate lines in the third line groups exhibit a voltage difference, and every adjacent pair of the gate lines in the fourth line groups exhibit a voltage difference,
wherein a voltage on at least one gate line in the third line group is different from a voltage on the gate line in the first line group, and in the first line group and the third line group arranged adjacently, the gate line in the third line group close to the first line group has a voltage difference from the gate line in the first line group close to the third line group;
a voltage on at least one gate line in the fourth line group is different from the voltage on the gate line in the first line group, and in the first line group and the fourth line group arranged adjacently, the gate line in the fourth line group close to the first line group has a voltage difference from the gate line in the first line group close to the fourth line group; and in the third line group and the fourth line group arranged adjacently, the gate line in the third line group close to the fourth line group has a voltage difference from the gate line in the fourth line group close to the third line group.

In the display panel according to one embodiment of the present application, each of the first line groups comprises a first gate line and a second gate line arranged adjacently; each of the third line groups comprises a fifth gate line and a first gate line, and the fifth gate line and the second gate line exhibit a voltage difference; in the first line group and the third line group arranged adjacently, the fifth gate line is close to the first line group;
each of the fourth line groups comprises a sixth gate line and the second gate line arranged adjacently, the sixth gate line and the first gate line exhibit a voltage difference, and in the first line group and the fourth line group arranged adjacently, the sixth gate line is close to the first line group.

In the display panel according to one embodiment of the present application, a voltage on the fifth gate line is equal to a voltage on the sixth gate line.

In the display panel according to one embodiment of the present application, the display panel further includes a second non-display area located on another side of the display area, wherein the second non-display area is arranged opposite to the first non-display area and provided with the first line groups and the second line groups, and wherein the first line groups and the second line groups in the first non-display area are electrically connected to odd-numbered ones of the gate scan lines, and the first line groups and the second line groups in the second non-display area are electrically connected to even-numbered ones of the gate scan lines.

In the display panel according to one embodiment of the present application, the display panel further includes a second non-display area located on another side of the display area, wherein the second non-display area is arranged opposite to the first non-display area and provided with the first line groups and the second line groups, and wherein the first line groups in the first non-display area are symmetrically arranged with the first line groups in the second non-display area, and the second line groups in the first non-display area are symmetrically arranged with the second line groups in the second non-display area.

In the display panel according to one embodiment of the present application, the first line groups or the second line groups are arranged in a same layer as the gate scan lines.

The present application further provides an electronic device, including a display panel of one of the above embodiments.

### Advantages

In a display panel and an electronic device provided in the present application, the display panel includes a plurality of first line groups and a plurality of second line groups disposed on a substrate. The first line groups and the second line groups are in different layers, and each of the first line groups and the second line groups includes at least two gate lines. Each gate line is electrically connected to a corresponding gate scan line. There is a voltage difference between every two adjacent gate lines in the first line groups. There is also a voltage difference between every two adjacent gate lines in the second line groups. In this configuration, adjacent gate lines in the same layer transmit different signals. When a short circuit occurs between adjacent gate lines in the same layer, it results in a noticeable change in voltage on the short-circuited gate lines. This change can be detected through a cell test, effectively reducing the chances of missed detections.

### BRIEF DESCRIPTION OF DRAWINGS

In order to provide a clearer illustration of the embodiments or technical solutions in the embodiments or the prior art, a brief introduction to the drawings required for the embodiments or descriptions of the prior art will be provided below. It is evident that the drawings described below are merely some embodiments of the invention, and those skilled in the art can obtain other drawings based on these drawings without creative efforts.

FIG. 1 is a schematic top view of a display panel according to one embodiment of the present application.

FIG. 2 is a detailed schematic structural view of a first non-display area in FIG. 1.

FIG. 3 is a schematic cross-sectional view taken along an M-M′ direction in FIG. 2.

FIG. 4 is a schematic cross-sectional view taken along an N-N′ direction in FIG. 2.

FIG. 5 is another schematic top view of the display panel according to one embodiment of the present application.

FIG. 6 is a detailed schematic structural view of the first non-display area in FIG. 5.

FIG. 7 is yet another schematic top view of the display panel according to one embodiment of the present application.

### DETAILED DESCRIPTION OF EMBODIMENTS

The descriptions of the various embodiments below are provided with reference to the accompanying drawings to illustrate specific embodiments that can be implemented in accordance with the present application. The directional terms used in the present application, such as “up”, “down”, “front”, “back”, “left”, “right”, “inner”, “outer”, “side”, and the like, are solely for reference with respect to the directions in the accompanying drawings. Therefore, the use of directional terms is for the purpose of explanation and understanding of the present application and not for limiting the scope of the present application. In the drawings, structurally similar units are indicated with the same reference numerals. In the accompanying drawings, for clarity of understanding and ease of description, thicknesses of certain layers and regions may be exaggerated. That is, the dimensions and thicknesses of each component shown in the accompanying drawings are not necessarily to scale and not limited to those shown in the drawings.

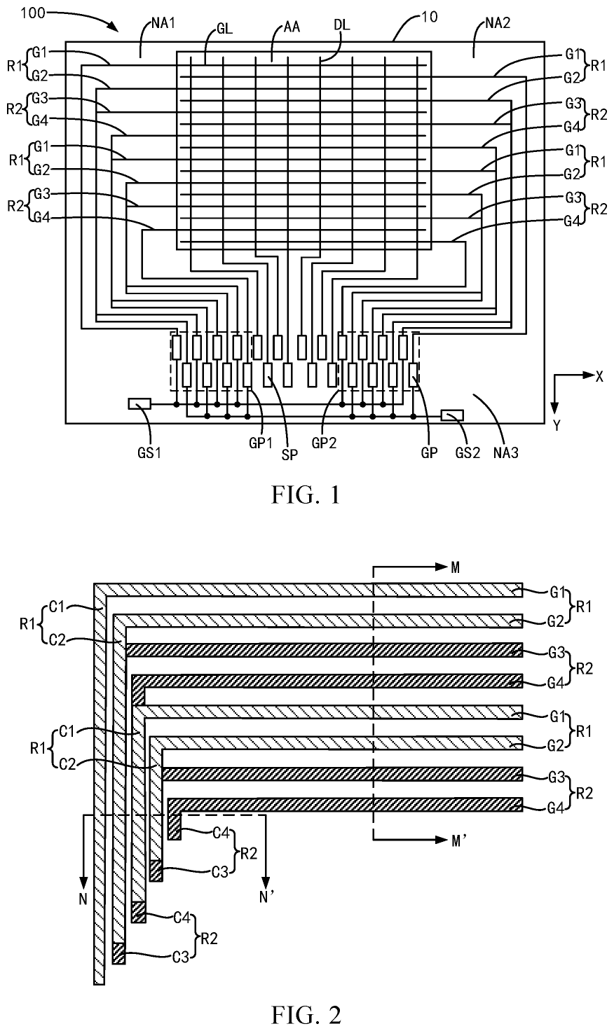

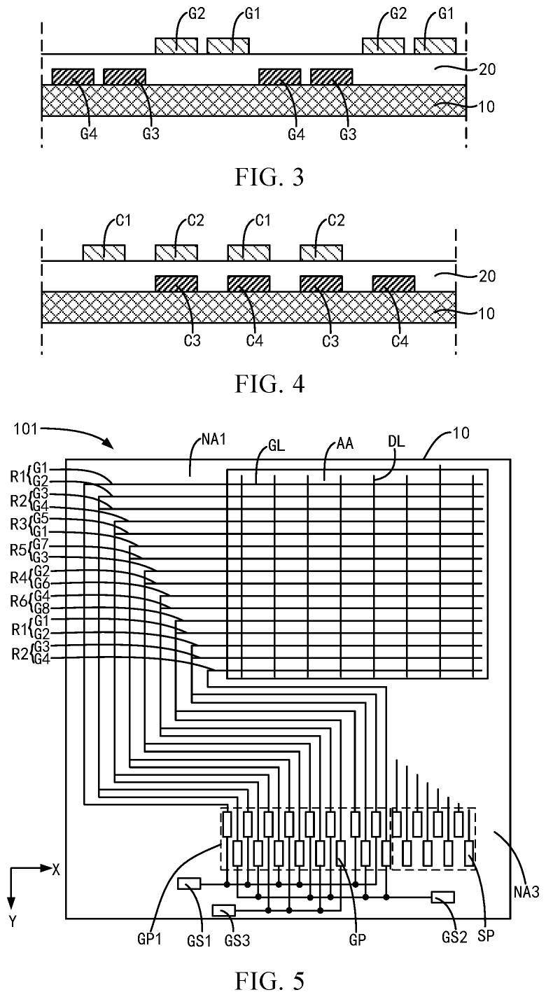

Please refer to FIGS. 1 to 4. FIG. 1 is a schematic top view of a display panel according to one embodiment of the present application. FIG. 2 is a detailed schematic structure view of a first non-display area in FIG. 1. FIG. 3 is a schematic cross-sectional view taken along an M-M′ direction in FIG. 2. FIG. 4 is a schematic cross-sectional view taken along an N-N′ direction in FIG. 2. The display panel 100 includes a display area AA and a non-display area surrounding the display area AA. The non-display area includes a first non-display area NA1, a second non-display area NA2, and a third non-display area NA3. The first non-display area NA1 is located on one side of the display area AA, while the second non-display area NA2 is located on another side of the display area AA, specifically on one side of the display area AA away from the first non-display area NA1, such that the first non-display area NA1 and the second non-display area NA2 are positioned opposite to each other. The third non-display area NA3 is located between the first non-display area NA1 and the second non-display area NA2. Optionally, the display panel 100 includes a liquid crystal display panel, an organic light-emitting diode (OLED) display panel, and the like.

The display panel 100 further includes a substrate 10 and multiple gate scan lines GL, multiple data lines DL, multiple first line groups R1, and multiple second line groups R2 positioned on the substrate 10. Optionally, the substrate 10 can be a rigid substrate or a flexible substrate. When the substrate 10 is a rigid substrate, the rigid substrate can include a glass substrate, or etc. When the substrate 10 is a flexible substrate, the flexible substrate can include a polyimide (PI) film, an ultra-thin glass film, or the like.

With reference to FIG. 1, multiple gate scan lines GL are positioned on the substrate 10 and are located within the display area AA. Each of these gate scan lines GL extends along a first direction X, and the gate scan lines GL are spaced apart along a second direction Y The data lines DL are also positioned on the substrate 10 within the display area AA. Each of these data lines DL extends along the second direction Y, and the data lines DL are spaced apart along the first direction X. The gate scan lines GL and the data lines DL intersect to define multiple pixels. The gate scan lines GL are used to provide gate drive signals to the pixels, and the data lines DL are used to provide data signals to the pixels. The first direction X is a horizontal direction, and the second direction Y is a vertical direction, but the present application is not limited to these orientations.

The first line groups R1 are positioned on the substrate 10 and are located within the first non-display area NA1. Each of the first line groups R1 includes at least two gate lines extending along the first direction X. Each gate line in the first line groups R1 is electrically connected to a corresponding gate scan line GL, and there is a voltage difference between every two adjacent gate lines.

The second line groups R2 are also positioned on the substrate 10 within the first non-display area NA1. Each of the second line groups R2 includes at least two gate lines extending along the first direction X. Each gate line in the second line groups is electrically connected to a corresponding gate scan line GL, and there is a voltage difference between every two adjacent gate lines. In this manner, adjacent gate lines in a same layer transmit different signals. When a short circuit occurs between adjacent gate lines in the same layer, because it is a short circuit between different signals, the voltage on the gate lines exhibits a significant change after the short circuit. Consequently, the voltage change can be detected through a cell test, effectively reducing the chances of missed detections.

Furthermore, the first line groups R1 and the second line groups R2 are located in different layers, and an orthographic projection of the gate lines in the second line groups R2 projected on the substrate 10 are alternately arranged with an orthographic projection of the gate lines in the first line groups R1 projected on the substrate 10.

Optionally, the first line groups R1 are formed by a first metal layer, and the second line groups R2 are formed by a second metal layer, with the first metal layer located on one side of the second metal layer that is away from the substrate 10. The first line groups R1 or the second line groups R2 are co-located in the same layer as the gate scan lines GL. A number of the gate lines in the first line group R1 is equal to a number of the gate lines in the second line group R2, and the voltage on the gate lines in the first line group R1 is equal to the voltage on the corresponding gate lines in the second line group R2.

Optionally, with reference to FIGS. 1 and 2, the first line group R1 includes a first gate line G1 and a second gate lines G2 adjacent to each other, with both the first gate line G1 and the second gate line G2 extending along the first direction X and being separated and electrically insulated from each other. There is a voltage difference between the first gate line G1 and the second gate line G2. For example, the voltage on the first gate line G1 is 9V, and the voltage on the second gate line G2 is −7V.

The second line group R2 includes a third gate line G3 and a fourth gate line G4 adjacent to each other, with both the third gate line G3 and the fourth gate line G4 extending along the first direction X and being separated and electrically insulated from each other. The voltage on the third gate line G3 is equal to the voltage on the first gate line G1, and the voltage on the fourth gate line G4 is equal to the voltage on the second gate line G2. Specifically, the voltage being equal means that the voltage amplitude is the same. For example, the voltage on the third gate line G3 is also 9V, and the voltage on the fourth gate line G4 is also −7V.

Additionally, since the first line group R1 and the second line group R2 are located in different metal layers, the first gate line G1 and the third gate line G3 are in different metal layers, and the second gate line G2 and the fourth gate line G4 are in different metal layers, as shown in FIG. 3. An interlayer insulating layer 20 is provided between the first gate line G1 and the third gate line G3 to insulate the gate lines in the first line group R1 from the gate lines in the second line group R2.

Furthermore, referring to FIGS. 1 and 2, each first line group R1 also includes multiple connecting lines. Within the same first line group R1, each connecting line is electrically connected to a corresponding gate line, and there is a voltage difference between every two adjacent connecting lines. The connecting lines within the first line group R1 and the gate lines within the first line group R1 are formed by the same metal layer. Optionally, the first line group R1 also includes a first connecting line C1 and a second connecting line C2 adjacent to each other. The first connecting line C1 is electrically connected to the first gate line G1, and part of the first connecting line C1 extends along the second direction Y The second connecting line C2 is electrically connected to the second gate line G2, and part of the second connecting line C2 extends along the second direction Y Along the first direction X, the first connecting line C1 and the second connecting line C2 are spaced apart and electrically insulated from each other.

Each second line group R2 also includes multiple connecting lines. In the same second line group R2, each connecting line is electrically connected to a corresponding gate line, and there is a voltage difference between every two adjacent connecting lines. In this way, adjacent connecting lines in the same layer transmit different signals. When a short circuit occurs between adjacent connecting lines in the same layer, because it is a short circuit between different signals, the voltage on the connecting lines after the short circuit exhibits a significant change. The voltage change can be detected through the cell test, thus effectively reducing the chances of missed detections. Certainly, to further reduce the chances of missed detections, along the first direction X, there is a voltage difference between any two adjacent connecting lines in the same metal layer.

The connecting lines in the second line group R2 and the gate lines in the first line group R1 are formed by the same metal layer. Thus, the connecting lines in the second line group R2 and the connecting lines in the first line group R1 are located in different metal layers. This arrangement helps reduce a width of the first non-display area NA1 in the first direction X, subsequently reducing a border of the display panel 100.

Optionally, the second line group R2 also includes a third connecting line C3 and a fourth connecting line C4 adjacent to each other. The third connecting line C3 is electrically connected to the third gate line G3, and part of the third connecting line C3 extends along the second direction Y The fourth connecting line C4 is electrically connected to the fourth gate line G4, and part of the fourth connecting line C4 extends along the second direction Y Along the first direction X, the third connecting line C3 and the fourth connecting line C4 are spaced apart and electrically insulated from each other.

To further reduce the width of the first non-display area NA1 in the first direction X, optionally, an orthographic projection of the connecting lines in the first line group R1 projected on the substrate 10 partially overlaps with an orthographic projection of the connecting lines in the second line group R2 projected on the substrate 10. As shown in FIG. 2, some of the connecting lines in the first line group R1 cover some of the connecting lines in the second line group R2. For example, part of the first connecting line C1 covers part of the fourth connecting line C4, and part of the second connecting line C2 partially covers part of the third connecting line C3. The term “cover” refers to the positional relationship of the connecting lines in the first line group R1 and the connecting lines in the second line group R2 in their orthographic projections on the substrate 10. For instance, part of the first connecting line C1 covering part of the fourth connecting line C4 means that the orthographic projection of the first connecting line C1 projected on the substrate 10 and the orthographic projection of the fourth connecting line C4 projected on the substrate 10 overlap in the first direction X, but the first connecting line C1 and the fourth connecting line C4 are still separated by the interlayer insulating layer 20, making the first connecting line C1 and the fourth connecting line C4 electrically insulated from each other, as shown in FIG. 4.

It should be noted that in FIG. 2, to clearly illustrate the connecting lines in the second line group R2 covered by the connecting lines in the first line group R1, part of the connecting lines in the first line group R1 are removed from the top of the connecting lines in the second line group R2. For example, in FIG. 2, the second connecting line C2 covers the third connecting line C3, causing the third connecting line C3 to be shielded by the second connecting line C2. To clearly show the third connecting line C3, part of the second connecting line C2 above the third connecting line C3 is removed.

Furthermore, the second non-display area NA2 is also provided with multiple first line groups R1 and multiple second line groups R2. The structure of the first line groups R1 in the second non-display area NA2 is the same as the structure of the first line groups R1 in the first non-display area NA1, and the structure of the second line groups R2 in the second non-display area NA2 is the same as the structure of the second line groups R2 in the first non-display area NA1. The difference lies in the fact that the first line groups R1 and second line groups R2 in the first non-display area NA1 are electrically connected to odd-numbered rows of the gate scan lines GL, while the first line groups R1 and second line groups R2 in the second non-display area NA2 are electrically connected to even-numbered rows of the gate scan lines GL.

Furthermore, in the third non-display area NA3, there is a terminal area that includes a first gate terminal area GP1, a second gate terminal area GP2, and a source terminal area SP located between the first gate terminal area GP1 and the second gate terminal area GP2. Both the first gate terminal area GP1 and the second gate terminal area GP2 include gate terminals GP. The gate terminals GP in the first gate terminal area GP1 are electrically connected to the first line groups R1 and the second line groups R2 in the first non-display area NA1, so as to provide gate drive signals to the first line groups R1 and the second line groups R2 in the first non-display area NA1. The gate terminals GP in the second gate terminal area GP2 are electrically connected to the first line groups R1 and the second line groups R2 in the second non-display area NA2, so as to provide gate drive signals to the first line groups R1 and the second line groups R2 in the second non-display area NA2. The source terminal area SP includes source terminals SP that are electrically connected to the data lines DL in the display area, so as to provide data signals to the data lines DL.

Certainly, to establish electrical connections between the gate terminals GP in the third non-display area NA3 and the first line groups R1 or the second line groups R2, there are also fan-out lines in the third non-display area. These fan-out lines are electrically connected to corresponding connecting lines in the line groups (including the first line groups R1 and the second line groups R2).

In order to provide different voltage signals to the connecting lines and the gate lines in each line group, the third non-display area NA3 is provided with a first signal access point GS1 and a second signal access point GS2. The first signal access point GS1 and the second signal access point GS2 offer different voltages, such as the first signal access point GS1 providing a voltage of 9V, and the second signal access point GS2 providing a voltage of −7V. The first gate line G1, the third gate line G3, the first connecting line C1, and the third connecting line C3 are all connected to the voltage of the first signal access point, while the second gate line G2, the fourth gate line G4, the second connecting line C2, and the fourth connecting line C4 are all connected to the voltage of the second signal access point.

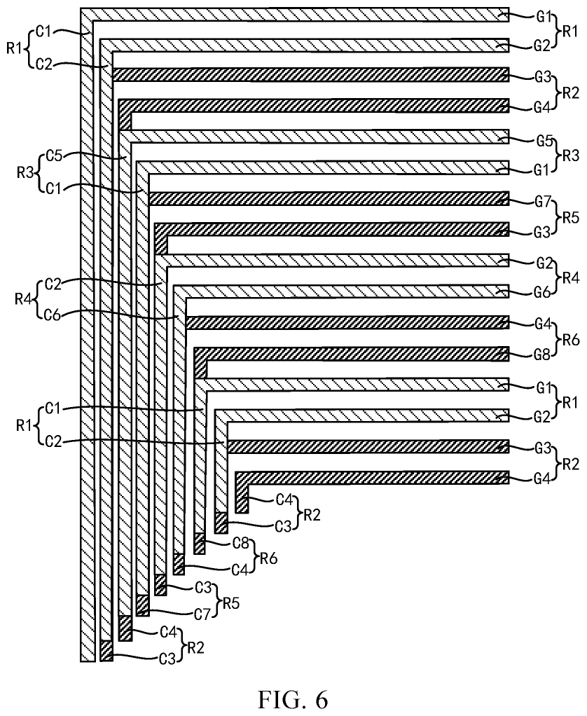

In one embodiment, referring to FIGS. 1 through 6, FIG. 5 depicts another schematic top view of the display panel 101 provided by the present application, and FIG. 6 shows a detailed structural view of the first non-display area in FIG. 5. In contrast to the previous embodiment, the display panel 101 further includes multiple third line groups R3 and multiple fourth line groups R4 set in the same layer as the first line groups R1. Between every two adjacent first line groups R1, there is one third line group R3 and one fourth line group R4. Both the third line group R3 and the fourth line group R4 consist of at least two gate lines. There is a voltage difference between every two adjacent gate lines in the third line group R3, and there is a voltage difference between every two adjacent gate lines in the fourth line group R4.

The voltage on at least one gate line in the third line group R3 is different from the voltage on the gate lines in the first line group R1. In the first line group R1 and the third line group R3 arranged adjacently, there is a voltage difference between the gate line in the third line group R3 near the first line group R1 and the gate line in the first line group R1 near the third line group R3.

The voltage on at least one gate line in the fourth line group R4 is different from the voltage on the gate lines in the first line group R1. In the first line group R1 and the fourth line group R4 arranged adjacently, there is a voltage difference between the gate line in the fourth line group R4 near the first line group R1 and the gate line in the first line group R1 near the fourth line group R4. Similarly, in the third line group R3 and the fourth line group R4 arranged adjacently, there is a voltage difference between the gate line in the third line group R3 near the fourth line group R4 and the gate line in the fourth line group R4 near the third line group R3.

The third line group R3 includes a fifth gate line G5 and the first gate line G1 arranged adjacently. There is a voltage difference between the fifth gate line G5 and the second gate line G2. In the first line group R1 and the third line group R3 arranged adjacently, the fifth gate line G5 is near the first line group R1. The fourth line group R4 includes a sixth gate line G6 and the second gate line G2 arranged adjacently. There is a voltage difference between the sixth gate line G6 and the first gate line G1. In the first line group R1 and the fourth line group R4 arranged adjacently, the sixth gate line G6 is near the first line group R1.

Correspondingly, the display panel 100 further includes multiple fifth line groups R5 and multiple sixth line groups R6 arranged in the same layer as the second line group R2. Between every two adjacent second line groups R2, there are a fifth line group R5 and a sixth line group R6. Each of the fifth line groups R5 and the sixth line groups R6 includes at least two gate lines. There is a voltage difference between every two adjacent gate lines in the fifth line group R5. There is a voltage difference between every two adjacent gate lines in the sixth line group R6.

At least one of the gate lines in the fifth line group R5 has a different voltage than the gate lines in the second line group R2. In the second line group R2 and the fifth line group R5 arranged adjacently, the gate line in the fifth line group R5 near the second line group R2 has a voltage difference from the gate line in the second line group R2 near the fifth line group R5.

At least one of the gate lines in the sixth line group R6 has a different voltage than the gate lines in the second line group R2. In the second line group R2 and the sixth line group R6 arranged adjacently, the gate line in the sixth line group R6 near the second line group R2 has a voltage difference from the gate line in the second line group R2 near the sixth line group R6 in the second line group R2. In addition, in the fifth line group R5 and the sixth line group R6 arranged adjacently, the gate line in the fifth line group R5 near the sixth line group R6 has a voltage difference from the gate line in the sixth line group R6 near the fifth line group R5.

The fifth line group R5 includes a seventh gate line G7 and the first gate line G1 arranged adjacently. There is a voltage difference between the sixth gate line G6 and the second gate line G2. In the second line group R2 and the fifth line group R5 arranged adjacently, the sixth gate line G6 is positioned close to the second line group R2. The sixth line group R6 includes an eighth gate line G8 and the second gate line G2 arranged adjacently. There is a voltage difference between the eighth gate line G8 and the first gate line G1. In the second line group R2 and the sixth line group R6 arranged adjacently, the eighth gate line G8 is positioned close to the second line group R2.

Optionally, the voltage on the fifth gate line G5 is equal to the voltage on the sixth gate line G6, the voltage on the seventh gate line G7 is equal to the voltage on the eighth gate line G8, and the voltage on the fifth gate line G5 is equal to the voltage on the seventh gate line G7. This allows the addition of only a third signal access point GS3 in the third non-display area NA3, which eliminates the need for adding too many signal access points in the third non-display area NA3, reducing the complexity of the cell test.

Understandably, as shown in FIG. 6, the third line group R3, the fourth line group R4, the fifth line group R5, and the sixth line group R6 all include connecting lines that are electrically connected to the gate lines. Optionally, the third line group R3 includes a fifth connecting line C5 and the first connecting line C1 arranged adjacently. The fourth line group R4 includes the second connecting line C2 and a sixth connecting line C6. The fifth line group R5 includes the seventh connecting line C7 and a third connecting line C3. The sixth line group R6 includes the fourth connecting line C4 and an eighth connecting line C8. In the same metal layer, any adjacent two connecting lines have a voltage difference along the first direction X. Please refer to the above embodiment for other descriptions, and repeated descriptions are omitted herein.

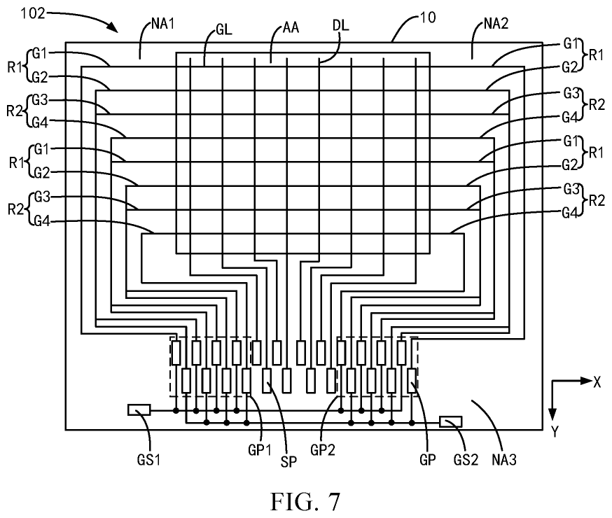

In another embodiment, please refer to FIGS. 1 to 7, where FIG. 7 is another schematic top view of the display panel provided in the present application. Unlike the previous embodiments, the display panel 102 also includes a second non-display area NA2 located on another side of the display area AA. The second non-display area NA2 is positioned opposite to the first non-display area NA1. The second non-display area NA2 includes the first line groups R1 and the second line groups R2. The first line group R1 in the first non-display area NA1 is symmetrically arranged with the first line group R1 in the second non-display area NA2. The second line group R2 in the first non-display area NA1 is symmetrically arranged with the second line group R2 in the second non-display area NA2. Further details are as described in the previous embodiments and will not be reiterated here.

Based on the same invention concept, the embodiments of the present application further provide an electronic device. The electronic device includes one of the display panels from the aforementioned embodiments. The electronic device can be a smartphone, a tablet, a television, or other electronic display products.

According to the above embodiments, it can be known that:

The application provides a display panel and an electronic device. The display panel includes multiple first line groups and multiple second line groups arranged on a substrate. The first line group and the second line group are positioned in different layers. Both the first line group and the second line group consist of at least two gate lines. Each gate line is electrically connected to a corresponding gate scan line. There is a voltage difference between every two adjacent gate lines in the first line groups. There is a voltage difference between every two adjacent gate lines in the second line groups. In this manner, adjacent gate lines in the same layer transmit different signals. When a short circuit occurs between adjacent gate lines in the same layer, because it is a short circuit between different signals, the voltage on the gate lines exhibits a significant change after the short circuit. Consequently, the voltage change can be detected through a cell test, effectively reducing the chances of missed detections.

In the above embodiments, each embodiment is described with its own emphasis. For parts that are not described in detail in a certain embodiment, please refer to the relevant descriptions in other embodiments.

The above description provides a detailed explanation of the embodiments of the present application. Specific examples have been used to explain the principles and implementation methods of the present application. The descriptions about the above embodiments are only provided for ease of understanding the technical solutions and the main ideas of the present application. It should be understood by those skilled in the art that modifications may be made to the technical solutions described in the various embodiments or certain technical features may be equivalently replaced. However, such modifications or replacements do not depart from the scope of the technical solutions of the embodiments of the present application.

1. A display panel, comprising a display area and a first non-display area located on one side of the display area, the display panel further comprising:
a substrate;
a plurality of gate scan lines disposed on the substrate and located in the display area, wherein each of the gate scan lines extends along a first direction, and the gate scan lines are arranged at intervals along a second direction;
a plurality of first line groups disposed on the substrate and located in the first non-display area, wherein each of the first line groups comprises at least two gate lines extending along the first direction, each of the gate lines is electrically connected to a corresponding one of the gate scan lines, and every two adjacent gate lines exhibit a voltage difference; and
a plurality of second line groups disposed on the substrate and located in the first non-display area, wherein each of the second line groups comprises at least two gate lines extending along the first direction, each of the gate lines is electrically connected to a corresponding one of the gate scan lines, and every two adjacent gate lines exhibit a voltage difference;
wherein the first line groups and the second line groups are located in different layers, and an orthographic projection of the gate lines in the second line groups projected on the substrate is alternately arranged with an orthographic projection of the gate lines in the first line groups projected on the substrate.

2. The display panel according to claim 1, wherein each of the first line groups further comprises a plurality of connecting lines, and in the same first line group, each of the connecting lines is electrically connected to a corresponding one of the gate lines, and every two adjacent connecting lines exhibit a voltage difference;
each of the second line groups further comprises a plurality of connecting lines, and in the same second line group, each of the connecting lines is electrically connected to a corresponding one of the gate lines, and every two adjacent connecting lines exhibit a voltage difference; and
an orthographic projection of the connecting lines in the first line groups projected on the substrate at least partially overlaps with an orthographic projection of the connecting lines in the second line groups projected on the substrate.

3. The display panel according to claim 2, wherein a number of the gate lines in the first line group is equal to a number of the gate lines in the second line group, and a voltage on each gate line in the first line group is equal to a voltage on the corresponding gate line in the second line group.

4. The display panel according to claim 3, wherein each of the first line groups comprises a first gate line and a second gate line arranged adjacent to each other, and each of the second line groups comprises a third gate line and a fourth gate line arranged adjacent to each other, wherein a voltage on the first gate line is equal to a voltage on the third gate line, and a voltage on the second gate line is equal to a voltage on the fourth gate line.

5. The display panel according to claim 2, further comprising a plurality of third line groups and a plurality of fourth line groups arranged in a same layer as the first line groups, wherein one of the third line groups and one of the fourth line groups are disposed between every two adjacent ones of the first line groups, each of the third line groups and the fourth line groups comprises at least two gate lines, every adjacent pair of the gate lines in the third line groups exhibit a voltage difference, and every adjacent pair of the gate lines in the fourth line groups exhibit a voltage difference,
wherein a voltage on at least one gate line in the third line group is different from a voltage on the gate line in the first line group, and in the first line group and the third line group arranged adjacently, the gate line in the third line group close to the first line group has a voltage difference from the gate line in the first line group close to the third line group;
a voltage on at least one gate line in the fourth line group is different from the voltage on the gate line in the first line group, and in the first line group and the fourth line group arranged adjacently, the gate line in the fourth line group close to the first line group has a voltage difference from the gate line in the first line group close to the fourth line group; and in the third line group and the fourth line group arranged adjacently, the gate line in the third line group close to the fourth line group has a voltage difference from the gate line in the fourth line group close to the third line group.

6. The display panel according to claim 5, wherein each of the first line groups comprises a first gate line and a second gate line arranged adjacently; each of the third line groups comprises a fifth gate line and a first gate line, and the fifth gate line and the second gate line exhibit a voltage difference; in the first line group and the third line group arranged adjacently, the fifth gate line is close to the first line group;
each of the fourth line groups comprises a sixth gate line and the second gate line arranged adjacently, the sixth gate line and the first gate line exhibit a voltage difference, and in the first line group and the fourth line group arranged adjacently, the second gate line is close to the first line group.

7. The display panel according to claim 6, wherein a voltage on the fifth gate line is equal to a voltage on the sixth gate line.

8. The display panel according to claim 1, further comprising a second non-display area located on another side of the display area, wherein the second non-display area is arranged opposite to the first non-display area and provided with the first line groups and the second line groups, and wherein the first line groups and the second line groups in the first non-display area are electrically connected to odd-numbered ones of the gate scan lines, and the first line groups and the second line groups in the second non-display area are electrically connected to even-numbered ones of the gate scan lines.

9. The display panel according to claim 1, further comprising a second non-display area located on another side of the display area, wherein the second non-display area is arranged opposite to the first non-display area and provided with the first line groups and the second line groups, and wherein the first line groups in the first non-display area are symmetrically arranged with the first line groups in the second non-display area, and the second line groups in the first non-display area are symmetrically arranged with the second line groups in the second non-display area.

10. The display panel according to claim 1, wherein the first line groups or the second line groups are arranged in a same layer as the gate scan lines.

11. An electronic device, comprising a display panel, wherein the display panel comprises a display area and a non-display area located on one side of the display area, the display panel further comprises:
a substrate;
a plurality of gate scan lines disposed on the substrate and located in the display area, wherein each of the gate scan lines extends along a first direction, and the gate scan lines are arranged at intervals along a second direction;
a plurality of first line groups disposed on the substrate and located in the first non-display area, wherein each of the first line groups comprises at least two gate lines extending along the first direction, each of the gate lines is electrically connected to a corresponding one of the gate scan lines, and every two adjacent gate lines exhibit a voltage difference; and
a plurality of second line groups disposed on the substrate and located in the first non-display area, wherein each of the second line groups comprises at least two gate lines extending along the first direction, each of the gate lines is electrically connected to a corresponding one of the gate scan lines, and every two adjacent gate lines exhibit a voltage difference;
wherein the first line groups and the second line groups are located in different layers, and an orthographic projection of the gate lines in the second line groups projected on the substrate is alternately arranged with an orthographic projection of the gate lines in the first line groups projected on the substrate.

12. The electronic device according to claim 11, wherein each of the first line groups further comprises a plurality of connecting lines, and in the same first line group, each of the connecting lines is electrically connected to a corresponding one of the gate lines, and every two adjacent connecting lines exhibit a voltage difference;
each of the second line groups further comprises a plurality of connecting lines, and in the same second line group, each of the connecting lines is electrically connected to a corresponding one of the gate lines, and every two adjacent connecting lines exhibit a voltage difference; and
an orthographic projection of the connecting lines in the first line groups projected on the substrate at least partially overlaps with an orthographic projection of the connecting lines in the second line groups projected on the substrate.

13. The electronic device according to claim 12, wherein a number of the gate lines in the first line group is equal to a number of the gate lines in the second line group, and a voltage on each gate line in the first line group is equal to a voltage on the corresponding gate line in the second line group.

14. The electronic device according to claim 13, wherein each of the first line groups comprises a first gate line and a second gate line arranged adjacent to each other, and each of the second line groups comprises a third gate line and a fourth gate line arranged adjacent to each other, wherein a voltage on the first gate line is equal to a voltage on the third gate line, and a voltage on the second gate line is equal to a voltage on the fourth gate line.

15. The electronic device according to claim 12, wherein the display panel further comprises a plurality of third line groups and a plurality of fourth line groups arranged in a same layer as the first line groups, wherein one of the third line groups and one of the fourth line groups are disposed between every two adjacent ones of the first line groups, each of the third line groups and the fourth line groups comprises at least two gate lines, every adjacent pair of the gate lines in the third line groups exhibit a voltage difference, and every adjacent pair of the gate lines in the fourth line groups exhibit a voltage difference,
wherein a voltage on at least one gate line in the third line group is different from a voltage on the gate line in the first line group, and in the first line group and the third line group arranged adjacently, the gate line in the third line group close to the first line group has a voltage difference from the gate line in the first line group close to the third line group;
a voltage on at least one gate line in the fourth line group is different from the voltage on the gate line in the first line group, and in the first line group and the fourth line group arranged adjacently, the gate line in the fourth line group close to the first line group has a voltage difference from the gate line in the first line group close to the fourth line group; and in the third line group and the fourth line group arranged adjacently, the gate line in the third line group close to the fourth line group has a voltage difference from the gate line in the fourth line group close to the third line group.

16. The electronic device according to claim 15, wherein each of the first line groups comprises a first gate line and a second gate line arranged adjacently; each of the third line groups comprises a fifth gate line and a first gate line, and the fifth gate line and the second gate line exhibit a voltage difference; in the first line group and the third line group arranged adjacently, the fifth gate line is close to the first line group;
each of the fourth line groups comprises a sixth gate line and the second gate line arranged adjacently, the sixth gate line and the first gate line exhibit a voltage difference, and in the first line group and the fourth line group arranged adjacently, the second gate line is close to the first line group.

17. The electronic device according to claim 16, wherein a voltage on the fifth gate line is equal to a voltage on the sixth gate line.

18. The electronic device according to claim 11, wherein the display panel further comprises a second non-display area located on another side of the display area; the second non-display area is arranged opposite to the first non-display area and provided with the first line groups and the second line groups; the first line groups and the second line groups in the first non-display area are electrically connected to odd-numbered ones of the gate scan lines; and the first line groups and the second line groups in the second non-display area are electrically connected to even-numbered ones of the gate scan lines.

19. The electronic device according to claim 11, wherein the display panel further comprises a second non-display area located on another side of the display area; the second non-display area is arranged opposite to the first non-display area and provided with the first line groups and the second line groups; the first line groups in the first non-display area are symmetrically arranged with the first line groups in the second non-display area; and the second line groups in the first non-display area are symmetrically arranged with the second line groups in the second non-display area.

20. The electronic device according to claim 11, wherein the first line groups or the second line groups are arranged in a same layer as the gate scan lines.
